(19) United States
(12) Patent Application Publication
(10) Pub. No.: US 2018/0241420 A1
(43) Pub. Date: Aug. 23, 2018

(54) IN-VEHICLE WIRELESS COMMUNICATION DEVICE

(71) Applicant: MITSUBISHI ELECTRIC CORPORATION, Tokyo (JP)

(72) Inventors: Hisao NAKANO, Tokyo (JP); Yasunori HOSHIHARA, Tokyo (JP); Masahiro NAKATSUKASA, Tokyo (JP)

(73) Assignee: MITSUBISHI ELECTRIC CORPORATION, Tokyo (JP)

(21) Appl. No.: 15/751,909

(22) PCT Filed: Nov. 11, 2015
(86) PCT No.: PCT/JP2015/081750

§ 371 Date: Feb. 12, 2018

(51) Int. Cl. H04B 1/00; H04B 1/3822; H01Q 13/20; H05K 9/00

(52) U.S. Cl. CPC H04B 1/0064; H04B 1/3822; H04W 88/06; H05K 9/0049; H01Q 13/203

(57) ABSTRACT

A shield box unit installed inside a vehicle and storing a mobile wireless terminal blocks external radio waves.

### TECHNICAL FIELD

The present invention relates to an in-vehicle wireless communication device for performing local wireless communication inside a vehicle as well as mobile communication.

### BACKGROUND ART

In recent years, devices having wireless communication functions have become widely used even in in-vehicle devices such as car navigation devices. For example, wireless communication using a Bluetooth (registered trademark, omitted hereinafter) method and a wireless local area network (LAN) method is used in many devices. Wireless communication using the Bluetooth method is used when a hands-free call, dial-up connection, or music playback is performed with devices such as mobile phones and audio players.

Furthermore, wireless communication using the wireless LAN method such as IEEE 802.11b/g/n is used when data such as video, music data, navigation data, or the like is transmitted to or from terminals such as smartphones and tablet personal computers (PCs).

The wireless frequency band of 2.4 GHz band for industrial, scientific, and medical uses is allocated to the wireless communication using the Bluetooth method and the wireless communication using the wireless LAN method. The 2.4 GHz band is called industry science medical (ISM) band. In addition to these methods, furthermore, the frequency band of 2.4 GHz is also allocated to cordless telephones.

Consequently, there is a possibility that when a public wireless LAN access point and an adjacent vehicle including a wireless LAN communication device exist at the location to which a vehicle moves, the wireless communication quality of in-vehicle equipment deteriorates due to radio-wave interference from these communication devices in the ISM band.

As a conventional technology against such radio-wave interference, Patent Literature 1 describes a windowpane capable of blocking only radio waves in a specific frequency band. By using this windowpane for a vehicle, it is possible to prevent radio-wave interference with wireless communication in the vehicle.

Furthermore, Patent Literature 2 describes a communication facility in which a mobile phone performs wireless communication with a base station for mobile communication inside an anechoic chamber that is shield from external radio waves are blocked. By using such an anechoic chamber, it is possible to prevent radio-wave interference with mobile communication.

### CITATION LIST

### Patent Literatures

Patent Literature 1: JP 2002-280824 A

Patent Literature 2: JP 2003-319447 A

### SUMMARY OF INVENTION

### Technical Problem

With the technology described in Patent Literature 1, however, the shielding effect against radio waves is lowered once a vehicle occupant opens a window. Thus, the window needs to be kept closed to continually prevent radio-wave interference, which leads to limitation of the usage of the vehicle.

Furthermore, the communication facility described in Patent Literature 2 assumes a user enters the anechoic chamber for use. Thus, the uses inside the vehicle are not taken into consideration, nor is the reduction in radio-wave interference with wireless communication using the wireless LAN method and the Bluetooth method taken into consideration.

The present invention has been made to solve the above-described issues, and an object of the present invention is to obtain an in-vehicle wireless communication device capable of stably reducing radio-wave interference with wireless communication inside a vehicle without limiting usage of the vehicle.

### Solution to Problem

An in-vehicle wireless communication device according to the present invention includes a shield box unit, first antenna units, and second antenna units. The shield box unit is installed inside a vehicle and stores a mobile wireless terminal to block external radio waves. The first antenna units are installed inside the shield box unit and connected to a wireless communication unit installed outside the shield box unit. The second antenna units are installed inside the shield box unit and connected to external antenna units installed outside the vehicle.

### Advantageous Effects of Invention

According to the present invention, since a shield box unit installed inside a vehicle and storing a mobile wireless terminal blocks external radio waves, it is possible to stably reduce radio-wave interference with wireless communication without limiting the usage of the vehicle.

### BRIEF DESCRIPTION OF DRAWINGS

FIG. 1 is a diagram illustrating an in-vehicle wireless communication device according to a first embodiment of the present invention and an example of a radio-wave environment thereof.

FIG. 2 is a block diagram illustrating a configuration of the in-vehicle wireless communication device according to the first embodiment.

FIG. 3A is a top view of a shield box unit, whereas FIG. 3B is a cross-sectional arrow view of the shield box unit, taken along line A-A of FIG. 3A.

### DESCRIPTION OF EMBODIMENTS

An embodiment of the present invention will be described below with reference to accompanying drawings to describe the present invention in further detail.

### First Embodiment

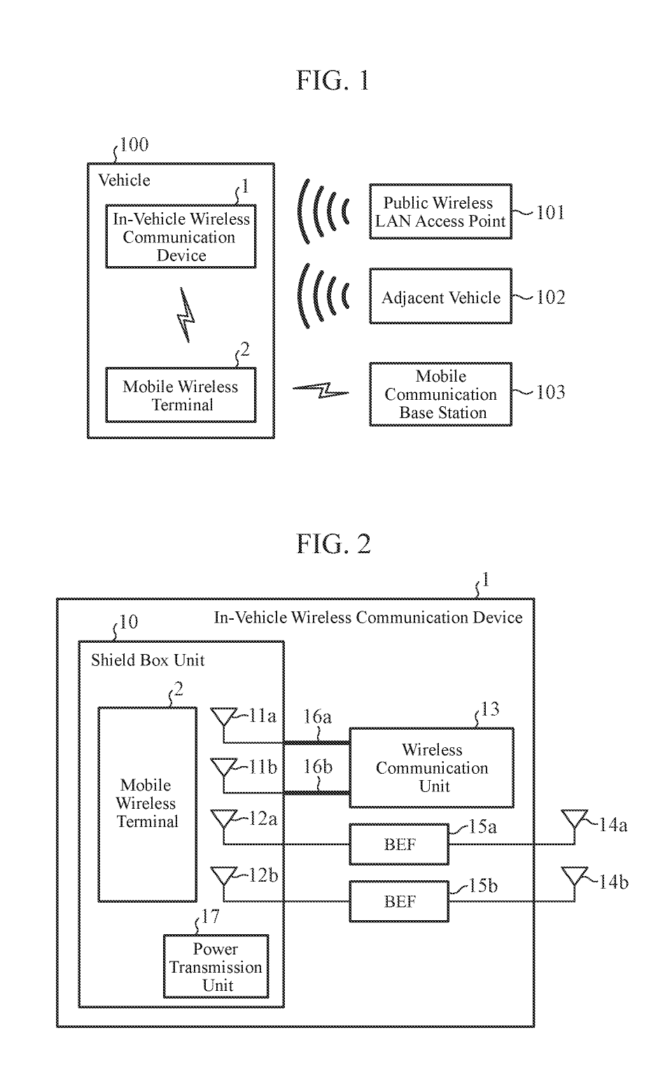

FIG. 1 is a diagram illustrating an in-vehicle wireless communication device 1 according to the first embodiment of the present invention and an example of its radio-wave environment. As illustrated in FIG. 1, wireless communication using the wireless LAN method or wireless communication using the Bluetooth method is performed between the in-vehicle wireless communication device 1 and a mobile wireless terminal 2 which are installed inside a vehicle 100. Furthermore, a public wireless LAN access point 101 and an in-vehicle communication device of a vehicle 102 also perform wireless communication using the wireless LAN method or wireless communication using the Bluetooth method. Moreover, mobile communication is performed between the mobile wireless terminal 2 and a mobile communication base station 103. Note that examples of the mobile wireless terminal 2 include a mobile phone, a smartphone, a personal handy-phone system (PHS), a mobile router, a tablet, and a game machine.

In some cases, when the vehicle 100 moves closer to the public wireless LAN access point 101 or the vehicle 102, the communication quality of the wireless communication between the in-vehicle wireless communication device 1 and the mobile wireless terminal 2 deteriorates due to radio-wave interference from the public wireless LAN access point 101 or the in-vehicle communication device of the vehicle 102. An object of the in-vehicle wireless communication device 1 according to the present invention is to reduce the influence of such radio-wave interference.

FIG. 2 is a block diagram illustrating a configuration of the in-vehicle wireless communication device 1 according to the first embodiment. As illustrated in FIG. 2, the in-vehicle wireless communication device 1 is a device that performs wireless communication using the wireless LAN method or wireless communication using the Bluetooth method with the mobile wireless terminal 2. As the configuration, a shield box unit 10, first antenna units 11a and 11b, second antenna units 12a and 12b, a wireless communication unit 13, band elimination filters (hereinafter referred to as BEFs) 15a and 15b, and leaky coaxial cables (hereinafter referred to as LCXs) 16a and 16b are included.

The shield box unit 10 is a box-shaped structure installed inside the vehicle 100. The shield box unit 10 stores the mobile wireless terminal 2 inside to block external radio waves. For example, the shield box unit 10 is formed with a metallic member such as a sheet metal, a resin member plated with a metallic thin film, or the like, and is grounded to the vehicle 100.

Thus, external radio waves are blocked by the shield box unit 10 installed inside the vehicle 100 and storing the mobile wireless terminal 2. Thus, just storing the mobile wireless terminal 2 in the shield box unit 10 can stably reduce radio-wave interference with wireless communication without limiting the usage of the vehicle 100.

The first antenna units 11a and 11b are wireless LAN or Bluetooth antennas and installed inside the shield box unit 10.

The second antenna units 12a and 12b are mobile communication antennas connected to external antenna units 14a and 14b and installed inside the shield box unit 10.

The wireless communication unit 13 is a wireless communication module installed outside the shield box unit 10. The wireless communication unit 13 is connected to the first antenna units 11a and 11b and performs wireless communication using the wireless LAN method or wireless communication using the Bluetooth method with the mobile wireless terminal 2.

Furthermore, the wireless communication unit 13 may be a wireless communication unit included in a device different from the in-vehicle wireless communication device 1, or may be a wireless communication device provided separately from the in-vehicle wireless communication device 1.

That is, in the in-vehicle wireless communication device 1, the wireless communication unit 13 provided outside the shield box unit 10 just needs to be connected to the first antenna units 11a and 11b, and the in-vehicle wireless communication device 1 does not necessarily include the wireless communication unit 13.

The external antenna units 14a and 14b are mobile communication antennas installed on the outside of the vehicle 100. The mobile wireless terminal 2 performs mobile communication with the mobile communication base station 103 via the second antenna units 12a and 12b and the external antenna units 14a and 14b.

The BEFs 15a and 15b are connected to the second antenna units 12a and 12b and the external antenna units 14a and 14b and block passage of radio waves in the wireless frequency band to be transmitted and received by the first antenna units 11a and 11b.

As described above, the external antenna units 14a and 14b receive radio waves outside the vehicle 100. When there exists the public wireless LAN access point 101 or an adjacent vehicle including a wireless LAN communication device in the vicinity of the vehicle 100, there is a possibility that radio waves in the wireless frequency band to be received and transmitted by the first antenna units 11a and 11b are also included in the radio waves received by the external antenna units 14a and 14b. Such radio waves are interference waves for the wireless communication using the first antenna units 11a and 11b.

Accordingly, the BEFs 15a and 15b for blocking the passage of the radio waves in the wireless frequency band to be transmitted and received by the first antenna units 11a and 11b are provided, so that the second antenna units 12a and 12b emit radio waves excluding the above-described wireless frequency band into the interior of the shield box unit 10. Thus, the interference waves do not enter the shield box unit 10, and radio-wave interference with the wireless communication between the mobile wireless terminal 2 and the wireless communication unit 13 can be prevented. Thus, the communication quality of the wireless communication between the mobile wireless terminal 2 and the wireless communication unit 13 can be enhanced.

Note that although FIG. 2 illustrates the case where the BEFs 15a and 15b are used, the filters are not limited thereto as long as the filters block the passage of the radio waves in the wireless frequency band to be transmitted and received by the first antenna units 11a and 11b. For example, a low pass filter (LPF) or a high pass filter (HPF) may be used.

Furthermore, when the influence of the interference waves received by the external antenna units 14a and 14b is not significant, the BEFs 15a and 15b may be omitted and the second antenna units 12a and 12b and the external antenna units 14a and 14b may be directly connected to each other.

The LCXs 16a and 16b are connected to the first antenna units 11a and 11b and the wireless communication unit 13 and leak radio waves in the wireless frequency band transmitted and received by the first antenna units 11a and 11b. For example, the LCXs 16a and 16b leak radio waves in the 2.4 GHz band. Accordingly, the LCXs 16a and 16b function as 2.4 GHz band antennas.

Since the LCXs 16a and 16b leak radio waves in the wireless frequency band transmitted and received by the first antenna units 11a and 11b, the wireless communication unit 13 can also perform wireless communication using the wireless LAN method or wireless communication using the Bluetooth method with communication equipment outside the shield box unit 10.

Note that radio waves leak from slits in the LCXs 16a and 16b. The slits are formed at constant intervals along the LCXs 16a and 16b. Therefore, the radio waves leaked from the LCXs 16a and 16b reach only a relatively narrow range inside a vehicle interior. Accordingly, wireless communication using the leaked radio waves between the wireless communication unit 13 and the above-described communication equipment is less prone to radio-wave interference from outside the vehicle 100.

Examples of the above-described communication equipment include wireless communication equipment such as wearable equipment brought into the vehicle interior.

When the wireless communication is not performed with the communication equipment outside the shield box unit 10, the LCXs 16a and 16b may be omitted and the first antenna units 11a and 11b and the wireless communication unit 13 may be directly connected to each other.

A power transmission unit 17 is provided inside the shield box unit 10 and wirelessly feeds power to the mobile wireless terminal 2 stored in the shield box unit 10. For example, wireless power feeding is performed using electromagnetic induction through coils provided in both the mobile wireless terminal 2 and the power transmission unit 17.

With this configuration, the mobile wireless terminal 2 can be charged inside the shield box unit 10. Accordingly, the mobile wireless terminal 2 can be prevented from running out of power and the use of the mobile wireless terminal 2 can be continued. By arranging the power transmission unit 17 inside the shield box unit 10, the emission of electromagnetic noise during the wireless power feeding can be reduced.

The first antenna units 11a and 11b inside the shield box unit 10 transmit and receive, to or from the mobile wireless terminal 2, radio waves in the wireless frequency band using the wireless LAN method or the Bluetooth method. The first antenna units 11a and 11b are connected to the wireless communication unit 13. Accordingly, wireless communication using the wireless LAN method or the Bluetooth method is performed between the mobile wireless terminal 2 and the wireless communication unit 13.

In this way, wireless communication is performed inside the shield box unit 10 which is blocked from external radio waves. Thus, it is less likely to be affected by the interference waves from outside the vehicle 100, and the quality of the wireless communication between the in-vehicle wireless communication device 1 and the mobile wireless terminal 2 is enhanced.

The second antenna units 12a and 12b inside the shield box unit 10 transmit and receive wireless communication radio waves for mobile communication to and from the mobile wireless terminal 2. The second antenna units 12a and 12b are connected to the external antenna units 14a and 14b. The external antenna units 14a and 14b transmit and receive wireless communication radio waves for mobile communication to and from the mobile communication base station 103. Accordingly, the mobile wireless terminal 2 stored in the interior of the shield box unit 10 performs wireless communication with the mobile communication base station 103 via the second antenna units 12a and 12b and the external antenna units 14a and 14b.

Wireless radio waves of the mobile communication base station 103 can be introduced to the interior of the shield box unit 10 which is blocked from external radio waves, enabling mobile communication.

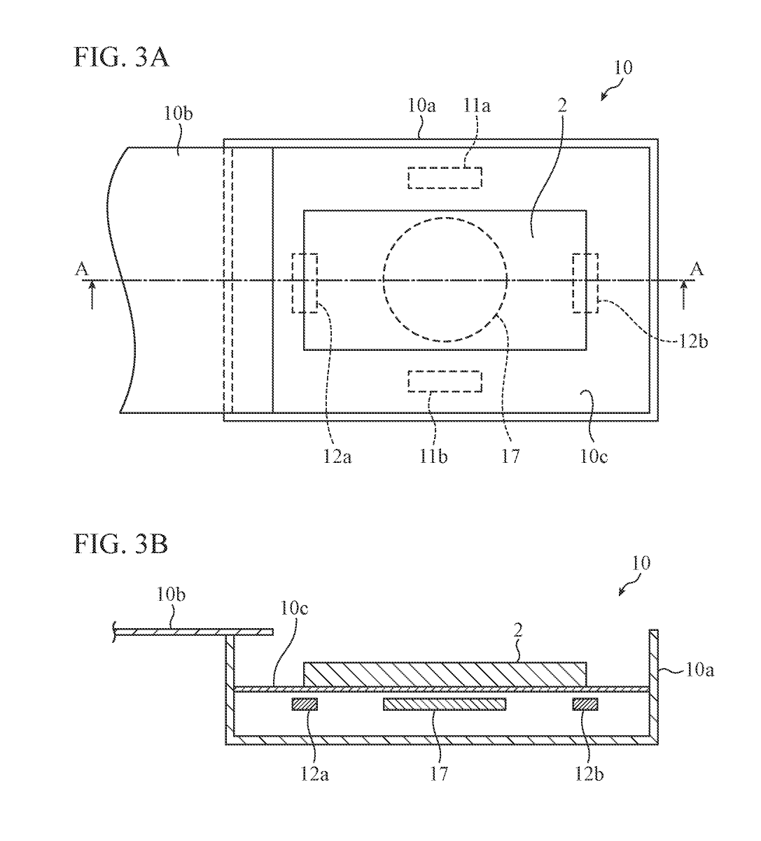

FIG. 3A is a top view of the shield box unit 10, whereas FIG. 3B is a cross-sectional arrow view of the shield box unit 10, taken along line A-A of FIG. 3A. As illustrated in FIGS. 3A and 3B, the shield box unit 10 includes a box-shaped structure 10a of which the top surface is open, a lid member 10b that opens and closes this opening section, and an installation surface 10c on which the mobile wireless terminal 2 is installed, in the inside thereof.

The mobile wireless terminal 2 is placed on the installation surface 10c, and the lid member 10b is closed, and then the mobile wireless terminal 2 is stored in the interior of the shield box unit 10. Note that a positioning rib may be provided on the installation surface 10c. Accordingly, even when vibrations or the like are transmitted, the rib can restrict the movement of the mobile wireless terminal 2.

The first antenna units 11a and 11b and the second antenna units 12a and 12b are installed below the installation surface 10c, as illustrated in FIG. 3B. Actually, there exist structures in which the first antenna units 11a and 11b and the second antenna units 12a and 12b are fixed to the bottom surface of the structure 10a, but its description is omitted in FIG. 3B.

Furthermore, the first antenna units 11a and 11b and the second antenna units 12a and 12b are arranged at positions close to the casing of the mobile wireless terminal 2 stored in the shield box unit 10.

For example, as illustrated in FIG. 3A, the first antenna units 11a and 11b and the second antenna units 12a and 12b are installed at positions along an outer shaped frame formed by projecting the outer shape of the mobile wireless terminal 2 onto the installation surface 10c.

As illustrated in FIG. 3A, the interior of the shield box unit 10 is large enough to store the mobile wireless terminal 2. Therefore, the first antenna units 11a and 11b and the second antenna units 12a and 12b are arranged in the interior of the shield box unit 10 at positions close to the casing of the mobile wireless terminal 2, for example, at a distance of 2 cm or less therefrom. The mobile wireless terminal 2 emits communication radio waves not only from a built-in antenna element but also from the casing. Thus, with the above-described arrangement, the first antenna units 11a and 11b and the second antenna units 12a and 12b can transmit and receive wireless communication radio waves with high radio field intensity to and from the mobile wireless terminal 2. As a result, it is possible to stabilize the communication quality of the wireless communication via the first antenna units 11a and 11b and the second antenna units 12a and 12b, and save power with the transmission power being kept low.

Note that a built-in antenna of the mobile wireless terminal 2 is generally installed on the lateral surface side in the interior of the casing of the mobile wireless terminal 2. In this case, by installing the first antenna units 11a and 11b and the second antenna units 12a and 12b as described above, the built-in antenna of the mobile wireless terminal 2 is brought in a state of being close to the first antenna units 11a and 11b and the second antenna units 12a and 12b.

Similarly, in this case, the first antenna units 11a and 11b and the second antenna units 12a and 12b can also transmit and receive wireless communication radio waves with high radio field intensity to and from the mobile wireless terminal 2. Therefore, it is possible to stabilize the communication quality of the wireless communication via the first antenna units 11a and 11b and the second antenna units 12a and 12b, and save power with the transmission power being kept low.

Although FIG. 3A illustrates the case where the first antenna units 11a and 11b and the second antenna units 12a and 12b are arranged in close proximity to the casing of the mobile wireless terminal 2, the arrangement is not limited thereto. Out of the first antenna units 11a and 11b and the second antenna units 12a and 12b, only the units that need to perform communication with high radio field intensity may be arranged in close proximity to the casing of the mobile wireless terminal 2, for example.

That is, at least one of either the first antenna units 11a and 11b or the second antenna units 12a and 12b just needs to be arranged in close proximity to the casing of the mobile wireless terminal 2.

Furthermore, the first antenna units 11a and 11b and the second antenna units 12a and 12b are arranged separately at a plurality of positions inside the shield box unit 10.

For example, as illustrated in FIG. 3A, the first antenna unit 11a, the second antenna unit 12a, the first antenna unit 11b, and the second antenna unit 12b are arranged in this order so as to surround the mobile wireless terminal 2. Moreover, the first antenna unit 11a and the first antenna unit 11b are arranged at positions facing each other across the mobile wireless terminal 2, while the second antenna unit 12a and the second antenna unit 12b are arranged at positions facing each other across the mobile wireless terminal 2.

Inside the shield box unit 10, multiple reflections of radio waves occur, causing the standing wave distribution. Accordingly, fluctuations in the radio field intensity occur depending on the positions of the first antenna units 11a and 11b or the second antenna units 12a and 12b. Furthermore, fluctuations in the radio field intensity also occur depending on the difference in the position and shape of an antenna element of each model of the mobile wireless terminal 2, or depending on the displacement in the installation position of the mobile wireless terminal 2 inside the shield box unit 10.

Thus, the first antenna units 11a and 11b and the second antenna units 12a and 12b are arranged separately at the plurality of positions inside the shield box unit 10 as described above, thereby reducing the possibility that the radio field intensity of all of the antennas is lowered.

In recent years, the mobile wireless terminal 2 having a multiple-input and multiple-output (MIMO) configuration has been increasing in number in the wireless LAN communication or the LTE communication, and, in many cases, uses a plurality of antennas. Therefore, the above-described arrangement of the antennas is suitable for the mobile wireless terminal 2 having the MIMO configuration. Similarly, the above-described arrangement of the antennas is also suitable for the mobile wireless terminal 2 having a diversity configuration using a plurality of antennas.

Note that in arranging the first antenna units 11a and 11b and the second antenna units 12a and 12b separately, the antenna units handling the same wireless frequency band are arranged such that the space therebetween is increased. For example, as illustrated in FIG. 3A, the first antenna unit 11a and the first antenna unit 11b are arranged at positions facing each other across the mobile wireless terminal 2 and spaced apart half or more of a wavelength to be handled. Similarly, the second antenna unit 12a and the second antenna unit 12b are arranged at positions facing each other across the mobile wireless terminal 2 and spaced apart half or more of a wavelength to be handled.

Such an arrangement can reduce the influence of the fluctuations in the radio field intensity.

Furthermore, it is possible to fix the arrangement of the first antenna units 11a and 11b and the second antenna units 12a and 12b inside the shield box unit 10, eliminating the need for adjustment for each model of the mobile wireless terminal 2. Moreover, this is also suitable for the mobile wireless terminal 2 having the MIMO configuration or the diversity configuration.

Note that in the case of reducing only the influence of the fluctuations in the radio field intensity in the first antenna units 11a and 11b, only the first antenna units 11a and 11b are arranged separately. Similarly, in the case of reducing only the influence of the fluctuations in the radio field intensity in the second antenna units 12a and 12b, only the second antenna units 12a and 12b are arranged separately.

That is, the in-vehicle wireless communication device 1 according to the present invention includes a configuration in which at least one of either the first antenna units 11a and 11b or the second antenna units 12a and 12b is arranged separately.

The whole or part of the shield box unit 10 may be formed of a member that is transparent or translucent to light in the visible light wavelength region.

Indium tin oxide (ITO) is an example of the member that blocks radio waves and is transparent or translucent.

Furthermore, the shield box unit 10 may be formed by forming or attaching a conductive mesh on a transparent or translucent resin member.

Moreover, the shield box unit 10 may be formed by thinly forming a metal film on a transparent or translucent resin member by sputtering, vapor deposition or the like.

With this configuration, the state of the mobile wireless terminal 2 inside the shield box unit 10 can be checked from the outside. Note that as long as the interior of the shield box unit 10 can be visually recognized from the outside thereof, at least part of the shield box unit 10 just needs to be transparent or translucent.

Furthermore, the whole or part of the shield box unit 10 may be formed of a member that blocks radio waves in the wireless frequency band to be transmitted and received by the first antenna units 11a and 11b while passing radio waves in the wireless frequency band to be transmitted and received by the second antenna units 12a and 12b.

For example, a Y-shaped patterned linear antenna is formed on the surface of at least one of the structure 10a and the lid member 10b. This Y-shaped linear antenna selects and attenuates only the frequency band used for the wireless LAN or the like. Thus, a member such as resin that passes the frequency band for mobile communication is used as a substrate member forming the Y-shaped linear antenna on the surface thereof.

With this configuration, the shield box unit 10 blocks radio waves in the wireless frequency band to be transmitted and received by the first antenna units 11a and 11b while passing radio waves in the wireless frequency band to be transmitted and received by the second antenna units 12a and 12b.

Therefore, mobile communication radio waves that pass through the shield box unit 10 can be transmitted and received between the second antenna units 12a and 12b and the mobile wireless terminal 2.

As a result, while maintaining the effect of the reduction in the radio-wave interference in the wireless communication in the vehicle interior, it is also possible to improve the radio field intensity of the mobile communication and enhance the performance of the mobile communication.

Although the example of forming the Y-shaped linear antenna has been described, the material of the shield box unit 10 may be selected in consideration of the wavelengths of the wireless communication used by the first antenna units 11a and 11b, the second antenna units 12a and 12b, and the wireless communication unit 13.

Furthermore, the shield box unit 10 has an opening and closing mechanism by which the amount of opening and closing of the lid member 10b is adjustable. For example, as illustrated in FIGS. 3A and 3B, the lid member 10b slides along an opening surface of the structure 10a. The lid member 10b may be structured so as to be opened and closed manually, but may also be structured so as to be opened and closed automatically in response to a driving force received from a driving unit such as a motor.

The mobile wireless terminal 2 has a function of detecting a received signal strength (received signal strength indication (RSSI)) of mobile communication.

Note that an example of a parameter indicating the received signal strength of mobile communication is RSSI and is not limited thereto.

The mobile wireless terminal 2 transmits the received signal strength to the wireless communication unit 13 through wireless communication via the first antenna units 11a and 11b.

The wireless communication unit 13 adjusts the amount of opening and closing of the lid member 10b, depending on the received signal strength from the mobile wireless terminal 2. For example, when the received signal strength is lower than a lower limit value of a predetermined signal strength range, the lid member 10b is moved in the opening direction. When the received signal strength is higher than an upper limit value of the predetermined signal strength range, the lid member 10b is moved in the closing direction.

By adjusting the lid member 10b in the opening direction when the radio field intensity of the mobile communication is insufficient, the radio field intensity of the mobile communication can be improved and the quality of the mobile communication can be enhanced.

In contrast, when the radio field intensity of the mobile communication is excessive, adjusting the lid member 10b in the closing direction can lower the radio field intensity of the mobile communication.

Note that as described above, the influence of the radio-wave interference with the above-described wireless communication in the vehicle interior can be reduced by performing wireless communication using the wireless LAN or Bluetooth method between the mobile wireless terminal 2 and the wireless communication unit 13 via the first antenna units 11a and 11b.

Furthermore, the communication quality of mobile communication between the mobile wireless terminal 2 in the vehicle interior and the outside of the vehicle 100 can be enhanced by performing the mobile communication by the mobile wireless terminal 2 via the second antenna units 12a and 12b and the external antenna units 14a and 14b.

As described above, the in-vehicle wireless communication device 1 according to the first embodiment includes the shield box unit 10, the first antenna units 11a and 11b, and the second antenna units 12a and 12b.

The shield box unit 10 is installed inside the vehicle 100 and stores the mobile wireless terminal 2 to block external radio waves. The first antenna units 11a and 11b are installed inside the shield box unit 10 and connected to the wireless communication unit 13 installed outside the shield box unit 10. The second antenna units 12a and 12b are installed inside the shield box unit 10 and connected to the external antenna units 14a and 14b installed outside the vehicle 100.

With this configuration, the external radio waves are blocked by the shield box unit 10 installed inside the vehicle 100 and storing the mobile wireless terminal 2. As a result, the radio-wave interference with the wireless communication can be reduced stably without limiting the usage of the vehicle 100.

In the in-vehicle wireless communication device 1 according to the first embodiment, furthermore, at least one of either the first antenna units 11a and 11b or the second antenna units 12a and 12b is arranged in close proximity to the casing of the mobile wireless terminal 2 stored in the shield box unit 10.

With this configuration, at least one of either the first antenna units 11a and 11b or the second antenna units 12a and 12b can transmit and receive wireless communication radio waves with high radio field intensity to and from the mobile wireless terminal 2. As a result, it is possible to stabilize the communication quality of the wireless communication, and save power with the transmission power being kept low.

In the in-vehicle wireless communication device 1 according to the first embodiment, moreover, at least one of either the first antenna units 11a and 11b or the second antenna units 12a and 12b is arranged separately at the plurality of positions inside the shield box unit 10.

Such a configuration can reduce the influence of the fluctuations in the radio field intensity.

Furthermore, it is possible to fix the arrangement of the first antenna units 11a and 11b and the second antenna units 12a and 12b inside the shield box unit 10, eliminating the need for adjustment for each model of the mobile wireless terminal 2. Moreover, this is also suitable for the mobile wireless terminal 2 having the MIMO configuration or the diversity configuration.

In the in-vehicle wireless communication device 1 according to the first embodiment, moreover, the second antenna units 12a and 12b and the external antenna units 14a and 14b are connected to each other via the BEFs 15a and 15b that block the passage of radio waves in the wireless frequency band to be transmitted and received by the first antenna units 11a and 11b. With this configuration, the interference waves are not introduced into the shield box unit 10, and radio-wave interference with the wireless communication between the mobile wireless terminal 2 and the wireless communication unit 13 can be prevented. Thus, the communication quality of the wireless communication between the mobile wireless terminal 2 and the wireless communication unit 13 can be enhanced.

In the in-vehicle wireless communication device 1 according to the first embodiment, moreover, the first antenna units l la and 11b and the wireless communication unit 13 are connected to each other via the LCXs 16a and 16b that leak radio waves in the wireless frequency band transmitted and received by the first antenna units 11a and 11b.

With this configuration, the wireless communication unit 13 can also perform wireless communication using the wireless LAN method or wireless communication using the Bluetooth method with equipment outside the shield box unit 10.

In the in-vehicle wireless communication device 1 according to the first embodiment, moreover, the shield box unit 10 is transparent or translucent with respect to light in the visible light wavelength region.

With this configuration, the state of the mobile wireless terminal 2 inside the shield box unit 10 can be visually recognized from the outside.

In the in-vehicle wireless communication device 1 according to the first embodiment, moreover, the shield box unit 10 blocks radio waves in the wireless frequency band to be transmitted and received by the first antenna units 11a and 11b while passing radio waves in the wireless frequency band to be transmitted and received by the second antenna units 12a and 12b.

With this configuration, while maintaining the effect of the reduction in the radio-wave interference in the wireless communication in the vehicle interior, it is also possible to improve the radio field intensity of the mobile communication and enhance the performance of the mobile communication.

In the in-vehicle wireless communication device 1 according to the first embodiment, moreover, the shield box unit 10 includes an opening and closing mechanism by which the amount of opening and closing is adjustable. By adjusting the lid member 10b in the opening direction when the radio field intensity of the mobile communication is insufficient, the radio field intensity of the mobile communication can be improved and the quality of the mobile communication can be enhanced. In contrast, when the radio field intensity of the mobile communication is excessive, adjusting the lid member 10b in the closing direction can lower the radio field intensity of the mobile communication.

In the in-vehicle wireless communication device 1 according to the first embodiment, moreover, the shield box unit 10 includes the power transmission unit 17 that wirelessly feeds power to the mobile wireless terminal 2 stored inside.

With this configuration, the mobile wireless terminal 2 can be charged inside the shield box unit 10. Accordingly, the mobile wireless terminal 2 can be prevented from running out of power and the use of the mobile wireless terminal 2 can be continued. By arranging the power transmission unit 17 inside the shield box unit 10, the emission of electromagnetic noise during the wireless power feeding can be reduced.

In the in-vehicle wireless communication device 1 according to the first embodiment, moreover, the wireless communication between the mobile wireless terminal 2 and the wireless communication unit 13 via the first antenna units 11a and 11b is wireless communication using the wireless LAN or Bluetooth method. Accordingly, the influence of the radio-wave interference with the wireless communication using the wireless LAN or Bluetooth method can be reduced.

In the in-vehicle wireless communication device 1 according to the first embodiment, moreover, the wireless communication of the mobile wireless terminal 2 via the second antenna units 12a and 12b and the external antenna units 14a and 14b is mobile communication. Accordingly, the communication quality of the mobile communication between the mobile wireless terminal 2 in the vehicle interior and the outside of the vehicle 100 can be enhanced.

Note that modifications of any component in the embodiment or omission of any component in the embodiment can be made in the present invention within the scope of the invention.

### INDUSTRIAL APPLICABILITY

The in-vehicle wireless communication device according to the present invention can stably reduce radio-wave interference with wireless communication inside a vehicle without limiting the usage of the vehicle. Therefore, the in-vehicle wireless communication device according to the present invention is suitable for, for example, a wireless communication device such as a navigation device having a wireless communication function.

### REFERENCE SIGNS LIST

1: In-vehicle wireless communication device, 2: Mobile wireless terminal, 10: Shield box unit, 10a: Structure, 10b: Lid member, 10c: Installation surface, 11a, 11b: First antenna unit, 12a, 12b: Second antenna unit, 13: Wireless communication unit, 14a, 14b: External antenna unit, 15a, 15b: Band elimination filter (BEF), 16a, 16b: Leaky coaxial cable (LCX), 17: Power transmission unit, 100, 102: Vehicle, 101: Public wireless LAN access point, 103: Mobile communication base station

1. An in-vehicle wireless communication device comprising:
a shield box to store a mobile wireless terminal and block an external radio wave, the shield box installed inside a vehicle;
at least one first antenna installed inside the shield box and connected to a wireless communication installed outside the shield box; and
at least one second antenna installed inside the shield box and connected to an external antenna installed outside the vehicle.

2. The in-vehicle wireless communication device according to claim 1,
wherein at least one of either the first antenna or the second antenna is arranged in close proximity to a casing of the mobile wireless terminal stored in the shield box.

3. The in-vehicle wireless communication device according to claim 1,
wherein the at least one first antenna includes a plurality of first antennas, and the at least one second antenna includes a plurality of second antennas, and
wherein at least one of either the first antennas or the second antennas is arranged separately it a plurality of positions inside the shield box.

4. The in-vehicle wireless communication device according to claim 1,
wherein the second antenna and the external antenna are connected via a filter to block passage of a radio wave in a wireless frequency band to be transmitted and received by the first antenna.

5. The in-vehicle wireless communication device according to claim 1,
wherein the first antenna and the wireless communication are connected via a leaky coaxial cable to leak a radio wave in a wireless frequency band transmitted and received by the first antenna.

6. The in-vehicle wireless communication device according to claim 1,
wherein at least part of the shield box is transparent or translucent to light in a visible light wavelength region.

7. The in-vehicle wireless communication device according to claim 1,
wherein at least part of the shield box blocks a radio wave in a wireless frequency band to be transmitted and received by the first antenna while passing a radio wave in a wireless frequency band to be transmitted and received by the second antenna.

8. The in-vehicle wireless communication device according to claim 1,
wherein the shield box includes an opening and closing mechanism by which an amount of opening and closing is adjustable.

9. The in-vehicle wireless communication device according to claim 1,
wherein the shield box includes a power transmission to wirelessly feed power to the mobile wireless terminal stored inside.

10. The in-vehicle wireless communication device according to claim 1,
wherein wireless communication between the wireless communication and the mobile wireless terminal via the first antenna is wireless communication using a wireless local area network or Bluetooth method.

11. The in-vehicle wireless communication device according to claim 1,
wherein wireless communication of the mobile wireless terminal via the second antenna and the external antenna is mobile communication.
